(19) United States
(12) Patent Application Publication
(10) Pub. No.: US 2017/0250206 A1
(43) Pub. Date: Aug. 31, 2017

(54) COMPOSITION FOR FORMING SILICA LAYER, METHOD FOR MANUFACTURING SILICA LAYER, AND SILICA LAYER

(71) Applicant: Samsung SDI Co., Ltd., Yongin-si (KR)

(72) Inventors: Kwen-Woo Han, Suwon-si (KR); Taeksoo Kwak, Suwon-si (KR); Kunbae Noh, Suwon-si (KR); Jinwoo Seo, Suwon-si (KR); Sooyeon Sim, Suwon-si (KR); Huichan Yun, Suwon-si (KR); Jiho Lee, Suwon-si (KR); Junyoung Jang, Suwon-si (KR); Byeong Gyu Hwang, Suwon-si (KR)

(21) Appl. No.: 15/263,192

(22) Filed: Sep. 12, 2016

(30) Foreign Application Priority Data
Feb. 26, 2016 (KR) 10-2016-0023589

(51) Int. Cl. H01L 27/12; B05D 1/00; B05D 3/02; H01L 21/02

(52) U.S. Cl. CPC H01L 27/1262; H01L 27/1248; H01L 21/02164; H01L 21/02337; H01L 21/02282; B05D 1/005; B05D 3/0254; H01L 21/02216; H01L 21/02222; G02F 1/133365

(57) ABSTRACT

A composition for forming a silica layer, a method for manufacturing a silica layer, a silica layer manufactured by the method, and an electronic device including the silica layer. The composition for forming a silica layer includes a silicon-containing polymer and a solvent compound represented by Chemical Formula 1:

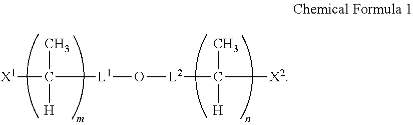

### CROSS-REFERENCE TO RELATED APPLICATION

This application claims priority to and the benefit of Korean Patent Application No. 10-2016-0023589, filed in the Korean Intellectual Property Office on Feb. 26, 2016, the entire content of which is incorporated herein by reference.

### BACKGROUND

1. Field

One or more aspects of example embodiments of the present disclosure are related to a composition for forming a silica layer, a method for manufacturing a silica layer, and a silica layer manufactured by the above method.

2. Description of the Related Art

A flat panel display may use a thin film transistor (TFT) including a gate electrode, a source electrode, a drain electrode, and a semiconductor as a switching device, and may be equipped with a gate line transferring a scan signal to control the thin film transistor and a data line transferring a signal applied to a pixel electrode. In some embodiments, an insulation layer is formed between the semiconductor and the several electrodes to separate them. The insulation layer may be a silica layer including a silicon component.

In general, a silica layer may be formed by coating polysilazane, polysiloxazane, or a mixture thereof onto a desired substrate and converting the coating layer into an oxide film. Such a film material should ensure suitable characteristics (e.g., coating properties) associated with fewer defects (for example, fewer particles in a film), and may be more easily coated on a substrate in order to obtain a uniform oxide film.

### SUMMARY

One or more example embodiments of the present disclosure are directed toward a composition for forming a silica layer that may minimize generation of defects in a layer and ensure suitable coating properties.

One or more example embodiments of the present disclosure are directed toward a method for manufacturing a silica layer using the composition for forming a silica layer.

One or more example embodiments of the present disclosure are directed toward a silica layer manufactured by the above method.

One or more example embodiments of the present disclosure are directed toward an electronic device including the silica layer.

One or more example embodiments of the present disclosure provide a composition for forming a silica layer including a silicon-containing polymer, and a solvent compound represented by Chemical Formula 1:

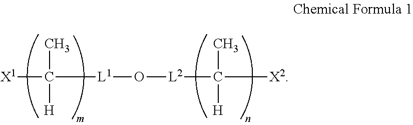

In Chemical Formula 1,

L¹ and L² may each independently be a single bond or a C₁ to C₅ alkylene group,

m and n may each independently be an integer of 0 to 2, and

X¹ and X² may each independently be a C₁ to C₁₀ alkyl group,

provided that when m and n are both (e.g., simultaneously) zero (0), at least one of X¹ and X² is a C₃ to C₁₀ iso-alkyl group or a C₄ to C₁₀ tert-alkyl group.

The solvent compound represented by Chemical Formula 1 may include 7 to 14 carbons in its structure.

The solvent compound represented by Chemical Formula 1 may include 8 to 12 carbons in its structure.

The solvent compound may include isobutylether, isoamylether, bis-(2,2-dimethyl propyl)-ether, bis-(1,1-dimethyl propyl)-ether, or a combination thereof.

A boiling point of the solvent compound may be less than or equal to about 200° C.

The silicon-containing polymer may include polysilazane, polysiloxazane, or a combination thereof.

The silicon-containing polymer may be included in an amount of about 0.1 wt % to about 30 wt % based on the weight of the composition for forming a silica layer.

One or more example embodiments of the present disclosure provide a method of manufacturing a silica layer including: coating the composition for forming a silica layer on a substrate, drying the substrate coated with the composition to produce a resultant, and curing the resultant at a temperature of about 250° C. to about 1,000° C. to manufacture a silica layer.

The curing may include a first curing under a water vapor atmosphere at a temperature of about 250° C. to about 1,000° C. and a second curing under a nitrogen atmosphere at a temperature of about 600° C. to about 1,000° C.

The coating of the composition for forming a silica layer may be performed by a spin-coating method.

One or more example embodiments of the present disclosure provide a silica layer manufactured using the above described method.

One or more example embodiments of the present disclosure provide an electronic device including the silica layer.

A composition for forming a silica layer according to an embodiment of the present disclosure includes a solvent compound having a set or predetermined structure. Accordingly, a silica layer manufactured using the composition for forming a silica layer may have uniform film properties.

### DETAILED DESCRIPTION

Example embodiments of the present disclosure will hereinafter be described in more detail, and may be easily performed by those who have knowledge in the related art. However, this disclosure may be embodied in many different forms, and should not be construed as being limited to the Example embodiments set forth herein.

As used herein, when a definition is not otherwise provided, the term ‘substituted’ refers to replacement of at least one hydrogen of a compound by a substituent selected from a halogen atom (F, Br, Cl, and/or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid or a salt thereof, a C₁ to C₂₀ alkyl group, a C₂ to C₂₀ alkenyl group, a C₂ to C₂₀ alkynyl group, a C₆ to C₃₀ aryl group, a C₇ to C₃₀ arylalkyl group, a C₁ to C₃₀ alkoxy group, a C₁ to C₂₀ heteroalkyl group, a C₂ to C₂₀ heteroaryl group, a C₃ to C₂₀ heteroarylalkyl group, a C₃ to C₃₀ cycloalkyl group, a C₃ to C₁₅ cycloalkenyl group, a C₆ to C₁₅ cycloalkynyl group, a C₂ to C₃₀ heterocycloalkyl group, and a combination thereof.

As used herein, when a definition is not otherwise provided, the term ‘hetero’ refers to a group including 1 to 3 heteroatoms selected from nitrogen (N), oxygen (O), sulfur (S), and phosphorus (P).

In the specification, the symbol “*” refers to a position that may be connected (e.g., coupled or bonded) with the same or a different atom or chemical formula.

Hereinafter, a composition for forming a silica layer according to an embodiment will be described in more detail.

A composition for forming a silica layer according to an embodiment of the present disclosure includes a silicon-containing polymer, and a solvent compound represented by Chemical Formula 1:

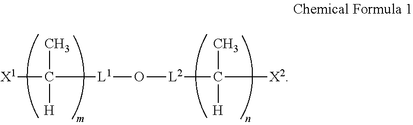

In Chemical Formula 1,

L¹ and L² may each independently be a single bond or a C₁ to C₅ alkylene group,

m and n may each independently be an integer from 0 to 2, and

X¹ and X² may each independently be a C₁ to C₁₀ alkyl group,

provided that when both m and n are zero (0), at least one of X¹ and X² is a C₃ to C₁₀ iso-alkyl group or a C₄ to C₁₀ tert-alkyl group.

The solvent of the composition for forming a silica layer according to an embodiment of the present disclosure may be represented by Chemical Formula 1, and may include one oxygen atom and three kinds of atoms in its structure; that is, an oxygen atom, a carbon atom, and a hydrogen atom.

The compound represented by Chemical Formula 1 may include at least one tertiary carbon in the structure. Herein, the term “tertiary carbon” refers to a carbon (e.g., a saturated carbon) that is substituted with groups other than hydrogen at three of four linking points (e.g., substituents).

For example, in Chemical Formula 1, m and n indicate the number (e.g., multiplicity) of —CH₃CH— moieties positioned to the left and right of an oxygen atom, respectively, and each —CH₃CH— moiety includes one tertiary carbon (e.g., the central carbon). For example, when m and n in Chemical Formula 1 are both 1, the compound represented by Chemical Formula 1 includes one tertiary carbon to the left and one tertiary carbon to the right of the oxygen atom.

In Chemical Formula 1, the functional groups represented by X¹ and X² at the terminal ends of the formula may each independently be a C₁ to C₁₀ alkyl group having one or more suitable structures (such as an n-alkyl group, an iso-alkyl group, a sec-alkyl group, a tert-alkyl group, and/or the like). However, when m and n in Chemical Formula 1 are both (e.g., simultaneously) 0, at least one of X¹ and X² may be a C₃ to C₁₀ iso-alkyl group or a C₄ to C₁₀ tert-alkyl group. When X¹ and X² are a C₃ to C₁₀ iso-alkyl group or a C₄ to C₁₀ tert-alkyl group, X¹ and X² may each independently include at least one tertiary carbon in their structures. When X¹ or X² is a C₃ to C₁₀ iso-alkyl group, non-limiting examples of X¹ or X² may include isopropyl, isobutyl, and isopentyl, and when X¹ or X² is a C₄ to C₁₀ tert-alkyl group, non-limiting examples of X¹ or X² may include tert-butyl, but embodiments of the present disclosure are not limited thereto.

Because semiconductors are integrated at a lower temperature, it is important to suitably control or select the properties of a polymer included in the composition for forming a silica layer in order to form a dense and uniform silica layer at the low temperature. In general, when the weight average molecular weight of a polymer is increased, the polymer may be more hydroscopic, and thus a relatively dense silica layer may be formed at a low temperature. However, when the weight average molecular weight of the polymer is increased, a higher number of particles may be generated from a nozzle tip during spin coating. Accordingly, it is important to select a suitable solvent for use in the composition for forming a silica layer.

According to an embodiment of the present disclosure, a composition for forming a silica layer includes a solvent compound having a structure of Chemical Formula 1 in order to secure affinity to a lower layer and to control generation of defects (e.g., a void or a hole defect). A solvent having an oxygen atom may be used in order to secure affinity to the lower layer; however, the oxygen atom in the solvent may react with moisture in the air and may thus absorb relatively more moisture. Accordingly, the composition for forming a silica layer according to an embodiment of the present disclosure may use a solvent including iso-alkyl groups, tert-alkyl groups, and/or other sterically bulky functional groups to counteract the reactivity of the oxygen atom with moisture in the air.

In Chemical Formula 1, L¹ and L² (each indicating a linking group) may each independently be a single bond (i.e., a direct bond) or a C₁ to C₂ alkylene group.

The compound represented by Chemical Formula 1 may have a symmetrical structure or an asymmetric structure with oxygen as the center atom. For example, the structure of the compound represented by Chemical Formula 1 may include about 7 to about 14 carbons, and in some embodiments about 8 to about 12 carbons. When the number of carbons is out of these ranges (e.g., higher), the layer may contain defects, but when the number of carbons is below these ranges (e.g., lower), the solvent may be more volatile and may cause coating problems during formation of a thin film.

For example, the solvent may include isobutylether, isoamylether, bis-(2,2-dimethyl propyl)-ether, bis-(1,1-dimethyl propyl)-ether, or a combination thereof, but embodiments of the present disclosure are not limited thereto.

For example, the solvent may have a boiling point of less than or equal to about 200° C., and in some embodiments about 90° C. to about 190° C., but embodiments of the present disclosure are not limited thereto.

The solvent may be a liquid at room temperature. The solvent may be a carbon compound represented by Chemical Formula 1, a mixture of two or more compounds each represented by Chemical Formula 1, or a mixture of a compound represented by Chemical Formula 1 with other components.

Hereinafter, the silicon-containing polymer of the composition for forming a silica layer will be described in more detail.

The silicon-containing polymer may include polysilazane, polysiloxazane, or a combination thereof, and may have a weight average molecular weight of about 1,000 g/mol to about 100,000 g/mol.

The silicon-containing polymer may include, for example, a moiety represented by Chemical Formula A:

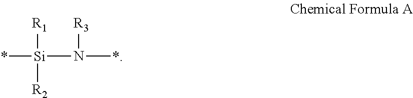

In Chemical Formula A, R₁ to R₃ may each independently be hydrogen, a substituted or unsubstituted C₁ to C₃₀ alkyl group, a substituted or unsubstituted C₃ to C₃₀ cycloalkyl group, a substituted or unsubstituted C₆ to C₃₀ aryl group, a substituted or unsubstituted C₇ to C₃₀ arylalkyl group, a substituted or unsubstituted C₁ to C₃₀ heteroalkyl group, a substituted or unsubstituted C₂ to C₃₀ heterocycloalkyl group, a substituted or unsubstituted C₂ to C₃₀ alkenyl group, a substituted or unsubstituted alkoxy group, a carboxyl group, an aldehyde group, a hydroxy group, or a combination thereof, and

“*” may indicate a linking point (e.g., coupling position).

For example, the silicon-containing polymer may be polysilazane produced by reacting a halosilane with ammonia.

For example, the silicon-containing polymer included in the composition for forming a silica layer may further include a moiety represented by Chemical Formula B in addition to the moiety represented by Chemical Formula A:

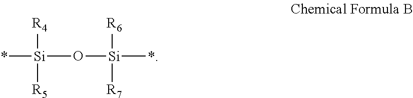

In Chemical Formula B, R₄ to R₇ may each independently be hydrogen, a substituted or unsubstituted C₁ to C₃₀ alkyl group, a substituted or unsubstituted C₃ to C₃₀ cycloalkyl group, a substituted or unsubstituted C₆ to C₃₀ aryl group, a substituted or unsubstituted C₇ to C₃₀ arylalkyl group, a substituted or unsubstituted C₁ to C₃₀ heteroalkyl group, a substituted or unsubstituted C₂ to C₃₀ heterocycloalkyl group, a substituted or unsubstituted C₂ to C₃₀ alkenyl group, a substituted or unsubstituted alkoxy group, a carboxyl group, an aldehyde group, a hydroxy group, or a combination thereof, and

“*” may indicate a linking point (e.g., coupling position).

In this case, the silicon-containing polymer may include a silicon-oxygen-silicon (Si—O—Si) moiety in its structure in addition to a silicon-nitrogen (Si—N) moiety, and the silicon-oxygen-silicon (Si—O—Si) moiety may reduce the degree of contraction and weaken or reduce any stress caused during heat curing treatment.

For example, the silicon-containing polymer may include the moiety represented by Chemical Formula A and the moiety represented by Chemical Formula B, and may further include a moiety represented by Chemical Formula C:

*—SiH₃ Chemical Formula C

The moiety represented by Chemical Formula C introduces a structure in which the terminal end of the compound is capped with hydrogen, and may be included in an amount of about 15 to about 35 wt % based on the total weight of Si—H bonds in the polysilazane and/or polysiloxazane structure. When the moiety of Chemical Formula C is included in the polysilazane and/or polysiloxazane structure within this amount range, loss of the SiH₃ moiety via conversion into SiH₄ when an oxidation reaction occurs during heat treatment may be prevented or reduced, and cracks in a filler pattern may be prevented or reduced.

For example, the silicon-containing polymer may be included in an amount of about 0.1 wt % to about 30 wt % based on the total weight of the composition for forming a silica layer.

The composition for forming a silica layer may further include a thermal acid generator (TAG).

The thermal acid generator may be an additive to improve the developing properties of the composition for forming a silica layer, and may thus enable the polymer of the composition to be developed at a relatively low temperature.

The thermal acid generator may include any compound that generates acid (H⁺) upon heating, with no particular limitations. For example, it may include a compound that is activated at a temperature of about 90° C. or higher, generates sufficient acid, and has low volatility.

The thermal acid generator may be, for example, selected from nitrobenzyl tosylate, nitrobenzyl benzenesulfonate, phenol sulfonate, and combinations thereof.

The thermal acid generator may be included in an amount of about 0.01 wt % to about 25 wt % based on the total weight of the composition for forming a silica layer. When the amount of the thermal acid generator is within these ranges, the polymer may be developed at a low temperature and may simultaneously have improved coating properties.

The composition for forming a silica layer may further include a surfactant. The surfactant is not particularly limited, and may be, for example, a non-ionic surfactant such as a polyoxyethylene alkyl ether (such as polyoxyethylene lauryl ether, polyoxyethylene stearyl ether, polyoxyethylene cetyl ether, polyoxyethylene oleyl ether, and/or the like), a polyoxyethylene alkylallyl ether (such as polyoxyethylenenonyl phenol ether and/or the like), a polyoxyethylene.polyoxypropylene block copolymer, a polyoxyethylene sorbitan fatty acid ester (such as sorbitan monolaurate, sorbitan monopalmitate, sorbitan monostearate, sorbitan monoleate, polyoxyethylene sorbitan monostearate, polyoxyethylene sorbitan trioleate, polyoxyethylene sorbitan tristearate, and/or the like); a fluorine-based surfactant (such as EFTOP EF301, EF303, EF352 (Tochem Products Co., Ltd.), MEGAFACE F171, F173 (Dainippon Ink & Chem., Inc.), FLUORAD FC430, FC431 (Sumitomo 3M), AsahiGuard AG710, Surflon S-382, SC101, SC102, SC103, SC104, SC105, SC106 (Asahi Glass Co., Ltd.), and/or the like), and/or another silicone-based surfactant (such as a organosiloxane polymer KP341 (Shin-Etsu Chemical Co., Ltd.)), and/or the like.

The surfactant may be included in an amount of about 0.001 wt % to about 10 wt % based on the total weight of the composition for forming a silica layer. When the surfactant is included within this range, solution dispersion, and simultaneously, uniformity in the thickness of a layer may be improved.

According to another embodiment, a method for manufacturing a silica layer includes coating the composition for forming a silica layer, drying the substrate coated with the composition for forming a silica layer to produce a resultant, and curing the resultant.

The composition for forming a silica layer may be coated through a solution process, for example, spin-coating, slit coating, inkjet printing, and/or the like. The substrate may be, for example, a device substrate such as a semiconductor, a liquid crystal and/or the like, but embodiments of the present disclosure are not limited thereto.

When the composition for forming a silica layer is completely or substantially completely coated, the substrate may be subsequently dried and cured. The drying and curing may be, for example, performed at a temperature greater than or equal to about 100° C. by applying energy (such as heat, ultraviolet (UV), microwaves, sound waves, ultrasonic waves, and/or the like).

For example, the drying may be performed at a temperature of about 100° C. to about 200° C., and a solvent may be thereby removed from the composition for forming a silica layer. In some embodiments, the curing may be performed at a temperature of about 250° C. to about 1,000° C., and the composition for forming a silica layer may be thereby converted into a thin oxide film. The curing may be, for example, performed primarily at a temperature of about 250° C. to about 1,000° C. under a water vapor atmosphere and secondarily at a temperature of about 600° C. to about 1,000° C. under a nitrogen atmosphere.

According to another embodiment, an electronic device including the silica layer manufactured according to the method is provided. The silica layer may be, for example an insulation layer, a separation layer, or a protective layer such as a hard coating layer, but embodiments of the present disclosure are not limited thereto.

According to yet another embodiment, an electronic device including the silica layer manufactured by the method described above is provided. The electronic device may be, for example, a display device (such as an LCD or an LED) or a semiconductor device.

The following examples illustrate embodiments of the present disclosure in more detail. However, embodiments of the present disclosure are not limited thereto.

### Preparation of Composition for Forming Silica Layer

### Polymerization Example 1: Synthesis of Polysilazane

A 2 L reactor equipped with a stirrer and a temperature controller was internally filled with dry nitrogen. 1,500 g of dry pyridine was injected into the reactor, sufficiently mixed, and kept warm at a temperature of 20° C. 100 g of dichlorosilane was slowly injected into the reaction mixture over one hour. Then, 70 g of ammonia was slowly injected over 3 hours. Subsequently, dry nitrogen was injected thereto for 30 minutes, and the ammonia remaining in the reactor was removed. The white slurry-phased product was filtered through a 1 μm Teflon™ (polytetrafluoroethylene) filter under a dry nitrogen atmosphere, yielding 1,000 g of a filtered solution. Then, 1,000 g of dry xylene was added thereto, and the mixture was adjusted to have a solid concentration of 20 wt % by repetitively (three times in total) substituting xylene for the pyridine with a rotary evaporator and then, filtering through a Teflon™ (polytetrafluoroethylene) filter having a pore size of 0.03 μm. The obtained polysilazane had an oxygen content of 3.8%, a SiH₃/SiH (total) ratio of 0.22, and a weight average molecular weight of 4,000 g/mol.

### Preparation of Composition for Forming Silica Layer

### Example 1

The polysilazane according to Polymerization Example 1 was mixed with an isoamyl ether solvent to prepare a composition for forming a silica layer having a solid content 15±0.1 wt %.

### Example 2

A composition for forming a silica layer was prepared according to substantially the same method as Example 1 except for using a mixed solvent dibutylether and isoamylether (a volume ratio=50:50) instead of the isoamylether.

### Example 3

A composition for forming a silica layer was prepared according to substantially the same method as Example 1 except for using isobutylether as a solvent.

### Example 4

A composition for forming a silica layer was prepared according to substantially the same method as Example 1 except for using bis-(2,2 dimethyl-propyl) ether as a solvent.

### Comparative Example 1

A composition for forming a silica layer was prepared according to substantially the same method as Example 1 except for using dipropyl ether as a solvent.

### Comparative Example 2

A composition for forming a silica layer was prepared according to substantially the same method as Example 1 except for using xylene as a solvent.

### Comparative Example 3

A composition for forming a silica layer was prepared according to substantially the same method as Example 1 except for using dibutyl ether as a solvent.

### Evaluation 1: Moisture Hygroscopicity of Solvent

The hygroscopicity of each solvent used in Examples 1 to 4 and Comparative Examples 1 to 3 was evaluated.

The hygroscopicity of each solvent used in Examples 1 to 4 and Comparative Examples 1 to 3 was evaluated at a temperature of 23° C.±2° C. under a relative humidity of 40%±10% according to Calculation Equation 1.

### Calculation Equation 1

Hygroscopicity of a solvent=(weight of moisture absorbed in the solvent when allowed to stand for 12 hours)/(weight of moisture absorbed in xylene when allowed to stand for 12 hours)

Calculation Equation 1 is used to evaluate the relative hygroscopicity of each solvent with a reference to the xylene solvent used in Comparative Example 2 (hygroscopicity of xylene=1.0).

### Evaluation 2: Hole Defect of Thin Film

3 mL of each composition for forming a silica layer according to Examples 1 to 4 and Comparative Examples 1 to 3 was dispensed from a nozzle tip of a spinner and spin-coated in the center of a patterned silicon wafer having a diameter of 8 inches at 1,500 rpm with a spin coater (K-SPIN8 equipment). The coated thin film was prebaked at a temperature of 150° C. Subsequently, the coated thin film was cured and converted into an oxide film at a temperature of 300° C. in a furnace supplied with water vapor. Then, greater than or equal to 1,000 Å of the oxide film was removed through etching, and the number of hole defects present as a concavo or convex disk (with a diameter greater than or equal to 50 nm) in the thin film was counted using defect inspection (KLA Tencor) equipment.

The results of Evaluations 1 to 2 are provided in Table 1:

TABLE 1

| | Comp. | Comp. | Comp. | | | | |
|---|---|---|---|---|---|---|---|
| | Ex. 1 | Ex. 2 | Ex. 3 | Ex. 1 | Ex. 2 | Ex. 3 | Ex. 4 |
| Hygroscopicity | 7.4 | 1.0 | 4.5 | 2.0 | 3.4 | 2.3 | 1.9 |
| of solvent | | (Ref.) | | | | | |
| Number of hole | 104 | 247 | 85 | 91 | 87 | 94 | 89 |
| defects | | | | | | | |

Referring to Table 1, the solvents used in Examples 1 to 4 showed relatively lower hygroscopicities compared to the solvents used in Comparative Examples 1 and 3.

In some embodiments, referring to Table 1, the compositions for forming a silica layer according to Examples 1 to 4 showed relatively fewer hole defects than the compositions for forming a silica layer according to Comparative Examples 1 to 3 when measured in Evaluation 2.

As used herein, expressions such as “at least one of”, “one of”, and “selected from”, when preceding a list of elements, modify the entire list of elements and do not modify the individual elements of the list. Further, the use of “may” when describing embodiments of the present disclosure refers to “one or more embodiments of the present disclosure”.

In addition, as used herein, the terms “use”, “using”, and “used” may be considered synonymous with the terms “utilize”, “utilizing”, and “utilized”, respectively.

As used herein, the terms “substantially”, “about”, and similar terms are used as terms of approximation and not as terms of degree, and are intended to account for the inherent deviations in measured or calculated values that would be recognized by those of ordinary skill in the art.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

While this present disclosure has been described in connection with what is presently considered to be practical Example embodiments, it is to be understood that the present disclosure is not limited to the disclosed embodiments, but, on the contrary, is intended to cover various modifications and equivalent arrangements included within the spirit and scope of the appended claims and equivalents thereof.

What is claimed is:

1. A composition for forming a silica layer, comprising:
a silicon-containing polymer, and
a solvent compound represented by Chemical Formula 1: 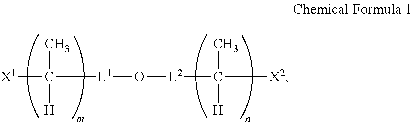
wherein, in Chemical Formula 1,
L¹ and L² are each independently a single bond or a C₁ to C₅ alkylene group,
m and n are each independently integers of 0 to 2, and
X¹ and X² are each independently a C₁ to C₁₀ alkyl group,
provided that when m and n are both zero (0), at least one of X¹ and X² is a C₃ to C₁₀ iso-alkyl group or a C₄ to C₁₀ tert-alkyl group.

2. The composition for forming a silica layer of claim 1, wherein the solvent compound represented by Chemical Formula 1 includes 7 to 14 carbons in its structure.

3. The composition for forming a silica layer of claim 2, wherein the solvent compound represented by Chemical Formula 1 includes 8 to 12 carbons in its structure.

4. The composition for forming a silica layer of claim 1, wherein the solvent compound includes isobutylether, isoamylether, bis-(2,2-dimethyl propyl)-ether, bis-(1,1-dimethyl propyl)-ether, or a combination thereof.

5. The composition for forming a silica layer of claim 1, wherein a boiling point of the solvent compound is less than or equal to about 200° C.

6. The composition for forming a silica layer of claim 1, wherein the silicon-containing polymer includes polysilazane, polysiloxazane, or a combination thereof.

7. The composition for forming a silica layer of claim 1, wherein the silicon-containing polymer is included in an amount of about 0.1 wt % to about 30 wt % based on the weight of the composition for forming a silica layer.

8. A method of manufacturing a silica layer, the method comprising:
coating the composition of claim 1 on a substrate,
drying the substrate coated with the composition to produce a resultant, and
curing the resultant at a temperature of about 250° C. to about 1,000° C. to manufacture a silica layer.

9. The method of claim 8, wherein the curing includes a first curing under a water vapor atmosphere at a temperature of about 250° C. to about 1,000° C. and a second curing under a nitrogen atmosphere at a temperature of about 600° C. to about 1,000° C.

10. The method of claim 8, wherein the coating of the composition for forming a silica layer is performed by a spin-coating method.

11. The method of claim 8, wherein the solvent compound includes isobutylether, isoamylether, bis-(2,2-dimethyl propyl)-ether, bis-(1,1-dimethyl propyl)-ether, or a combination thereof.

12. The method of claim 8, wherein a boiling point of the solvent compound is less than or equal to about 200° C.

13. The method of claim 8, wherein the silicon-containing polymer includes polysilazane, polysiloxazane, or a combination thereof.

14. The method of claim 8, wherein the silicon-containing polymer is included in an amount of about 0.1 wt % to about 30 wt % based on the weight of the composition for forming a silica layer.

15. A silica layer manufactured by the method of claim 8.

16. An electronic device comprising the silica layer of claim 11.

17. An electronic device comprising a silica layer, the silica layer being a derivative of the composition of claim 1.
